(19) United States
(12) Patent Application Publication
(10) Pub. No.: US 2022/0208996 A1
(43) Pub. Date: Jun. 30, 2022

(54) METHODS AND APPARATUS FOR PROCESSING A SUBSTRATE

(71) Applicant: Applied Materials, Inc., Santa Clara, CA (US)

(72) Inventors: Shubneesh BATRA, Boise, ID (US); Guan Huei SEE, Singapore (SG)

(21) Appl. No.: 17/139,169

(22) Filed: Dec. 31, 2020

(51) Int. Cl. H01L 29/66; H01L 29/24; H01L 29/49; H01L 29/786; H01L 21/4757; H01L 21/4763

(52) U.S. Cl. CPC H01L 29/66969; H01L 29/24; H01L 21/47635; H01L 29/7869; H01L 21/47573; H01L 29/4908

(57) ABSTRACT

Methods and apparatus for processing a substrate are provided herein. For example, a method can include depositing a first metal layer on a substrate and etching the first metal layer to form a gate electrode, depositing a dielectric layer atop the gate electrode, depositing a semi-conductive oxide layer atop the dielectric layer to cover a portion of the gate electrode, etching the dielectric layer from a portion of the gate electrode that is not covered by the semi-conductive oxide layer to form a gate access via, and depositing a second metal layer atop the dielectric layer and the semi-conductive oxide layer, and within the gate access via.

### FIELD

Embodiments of the present disclosure generally relate to a methods and apparatus for processing a substrate, and more particularly, to methods and apparatus configured for low-temperature thin film transistor as active device on polymer substrate.

### BACKGROUND

In today's semiconductor backend packaging applications, substrates can include multiple die inside the same semiconductor package, e.g., in applications where high performance and low power are critical. For example, high performance and/or low power are, typically, required for communication between one or more integrated circuit (IC) chips disposed on substrates—which can be established using either a silicon (Si) or one or more polymers as an interposer (redistribution layer (RDL) or substrate). For example, the polymer interposer (e.g., for 2.1D or 3D systems in package integration) is traditionally passive interconnects (e.g., copper) that are integrated using a Si substrate, e.g., a chip or layer with through-silicon vias (TSV) for communication. Such devices, however, require signals to pass through a lossy Si substrate/TSV and consume expensive logic real estate on the substrate.

Accordingly, the inventors have provided methods and apparatus configured for low-temperature thin film transistor as active device on polymer substrate.

### SUMMARY

Methods and apparatus for processing a substrate are provided herein. In some embodiments, a method for processing a substrate includes depositing a first metal layer on a substrate and etching the first metal layer to form a gate electrode, depositing a dielectric layer atop the gate electrode, depositing a semi-conductive oxide layer atop the dielectric layer to cover a portion of the gate electrode, etching the dielectric layer from a portion of the gate electrode that is not covered by the semi-conductive oxide layer to form a gate access via, and depositing a second metal layer atop the dielectric layer and the semi-conductive oxide layer, and within the gate access via.

In accordance with at least some embodiments, a non-transitory computer readable storage medium having stored thereon instructions that when executed by a processor performs a method of processing a substrate. The method includes depositing a first metal layer on a substrate and etching the first metal layer to form a gate electrode, depositing a dielectric layer atop the gate electrode, depositing a semi-conductive oxide layer atop the dielectric layer to cover a portion of the gate electrode, etching the dielectric layer from a portion of the gate electrode that is not covered by the semi-conductive oxide layer to form a gate access via, and depositing a second metal layer atop the dielectric layer and the semi-conductive oxide layer, and within the gate access via.

In accordance with at least some embodiments, an apparatus for use with a thin film transistor includes a first metal layer deposited on a carrier substrate and having a gate electrode formed thereon, a dielectric layer deposited atop the gate electrode, a semi-conductive oxide layer deposited atop the dielectric layer to cover a portion of the gate electrode, a gate access formed in a portion of the gate electrode that is not covered by the semi-conductive oxide layer, and a second metal layer is deposited atop the dielectric layer and the semi-conductive oxide layer, and within the gate access via.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a flowchart of a method of processing a substrate in accordance with at least some embodiments of the present disclosure.

FIG. 2 is a diagram of an apparatus in accordance with at least some embodiments of the present disclosure.

FIGS. 3A-3K are sequencing diagrams of substrate formation using the method of FIG. 2 in accordance with at least some embodiments of the present disclosure.

FIG. 3L is a top view of the area of detail of FIG. 3F in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of a methods and apparatus for processing a substrate are provided herein. For example, methods can include embedding a thin film transistor (TFT) within a matrix of polymer RDL interposer, e.g., for fan-out wafer-level packaging, embedded packaging in substrate technology, etc. The TFT can be embedded onto one or more layers (e.g., first layer, second layer, third layer, etc.) of the RDL interposer. In at least some embodiments, the TFT can be embedded on a first metal layer of the RDL. The TFT gate can be formed where gate metal is placed at the bottom layer, top or dual-gates (top & bottom). The TFT can be formed using one or more suitable metal oxides (e.g., zinc oxide, aluminum doped zinc oxide, indium-zinc oxide, indium-gallium-zinc-oxide (IGZO), etc.) to form an active channel. Embedding the TFT within a matrix of polymer or RDL interposer provides signal buffering having a shorter path, e.g., without a need for Si substrate/TSV, thus enabling better performance and lower system integration costs, when compared to conventional interposers for fan-out wafer-level packaging, embedded packaging in substrate technology, etc.

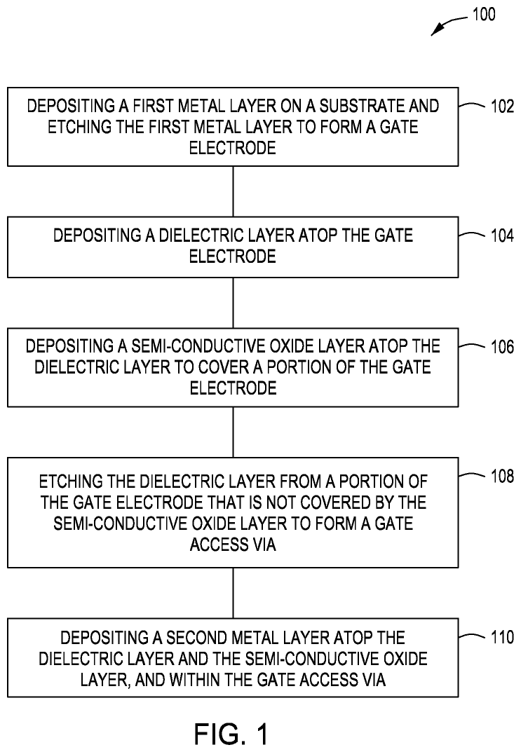

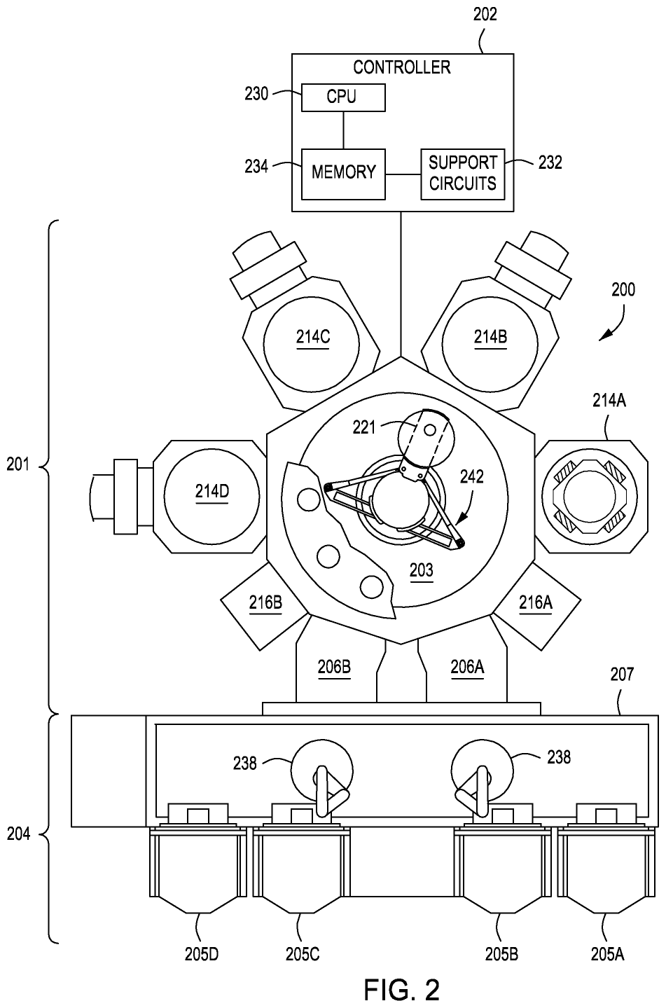

FIG. 1 is a flowchart of a method 100 for processing a substrate, and FIG. 2 is a tool 200 (or apparatus) that can used for carrying out the method 100, in accordance with at least some embodiments of the present disclosure.

The method 100 may be performed in the tool 200 including any suitable process chambers configured for one or more of physical vapor deposition (PVD), chemical vapor deposition (CVD), such as plasma-enhanced CVD (PECVD) and/or atomic layer deposition (ALD), such as plasma-enhanced ALD (PEALD) or thermal ALD (e.g., no plasma formation). Exemplary processing systems that may be used to perform the inventive methods disclosed herein are commercially available from Applied Materials, Inc., of Santa Clara, Calif. Other process chambers, including those from other manufacturers, may also be suitably used in connection with the teachings provided herein.

The tool 200 can be embodied in individual process chambers that may be provided in a standalone configuration or as part of a cluster tool, for example, an integrated described below with respect to FIG. 2. Examples of the integrated tool are available from Applied Materials, Inc., of Santa Clara, Calif. The methods described herein may be practiced using other cluster tools having suitable process chambers coupled thereto, or in other suitable process chambers. For example, in some embodiments, the inventive methods discussed above may be performed in an integrated tool such that there are limited or no vacuum breaks between processing steps. For example, reduced vacuum breaks may limit or prevent contamination (e.g., oxidation) of the titanium barrier layer or other portions of the substrate.

The integrated tool includes a processing platform 201 (vacuum-tight processing platform), a factory interface 204, and a system controller 202. The processing platform 201 comprises multiple process chambers, such as 214A, 214B, 214C, and 214D operatively coupled to a transfer chamber 203 (vacuum substrate transfer chamber). The factory interface 204 is operatively coupled to the transfer chamber 203 by one or more load lock chambers (two load lock chambers, such as 206A and 206B shown in FIG. 2).

In some embodiments, the factory interface 204 comprises a docking station 207, a factory interface robot 238 to facilitate the transfer of one or more semiconductor substrates (wafers). The docking station 207 is configured to accept one or more front opening unified pod (FOUP). Four FOUPS, such as 205A, 205B, 205C, and 205D are shown in the embodiment of FIG. 2. The factory interface robot 238 is configured to transfer the substrates from the factory interface 204 to the processing platform 201 through the load lock chambers, such as 206A and 206B. Each of the load lock chambers 206A and 206B have a first port coupled to the factory interface 204 and a second port coupled to the transfer chamber 203. The load lock chamber 206A and 206B are coupled to a pressure control system (not shown) which pumps down and vents the load lock chambers 206A and 206B to facilitate passing the substrates between the vacuum environment of the transfer chamber 203 and the substantially ambient (e.g., atmospheric) environment of the factory interface 204. The transfer chamber 203 has a vacuum robot 242 disposed within the transfer chamber 203. The vacuum robot 242 is capable of transferring substrates 221 between the load lock chamber 206A and 206B and the process chambers 214A, 214B, 214C, and 214D.

In some embodiments, the process chambers 214A, 214B, 214C, and 214D, are coupled to the transfer chamber 203. The process chambers 214A, 214B, 214C, and 214D comprise at least an ALD chamber, a CVD chamber, a PVD chamber, an e-beam deposition chamber, an electroplating, electroless (EEP) deposition chamber, a wet etch chamber, a dry etch chamber, an anneal chamber, and/or other chamber suitable for performing the methods described herein.

In some embodiments, one or more optional service chambers (shown as 216A and 216B) may be coupled to the transfer chamber 203. The service chambers 216A and 216B may be configured to perform other substrate processes, such as degassing, bonding, chemical mechanical polishing (CMP), wafer cleaving, etching, plasma dicing, orientation, substrate metrology, cool down and the like.

The system controller 202 controls the operation of the tool 200 using a direct control of the process chambers 214A, 214B, 214C, and 214D or alternatively, by controlling the computers (or controllers) associated with the process chambers 214A, 214B, 214C, and 214D and the tool 200. In operation, the system controller 202 enables data collection and feedback from the respective chambers and systems to optimize performance of the tool 200. The system controller 202 generally includes a central processing unit (CPU) 230, a memory 234, and a support circuit 232. The CPU 230 may be any form of a general-purpose computer processor that can be used in an industrial setting. The support circuit 232 is conventionally coupled to the CPU 230 and may comprise a cache, clock circuits, input/output subsystems, power supplies, and the like. Software routines, such as processing methods as described above may be stored in the memory 234 (e.g., non-transitory computer readable storage medium having instructions stored thereon) and, when executed by the CPU 230, transform the CPU 230 into a system controller 202 (specific purpose computer). The software routines may also be stored and/or executed by a second controller (not shown) that is located remotely from the tool 200.

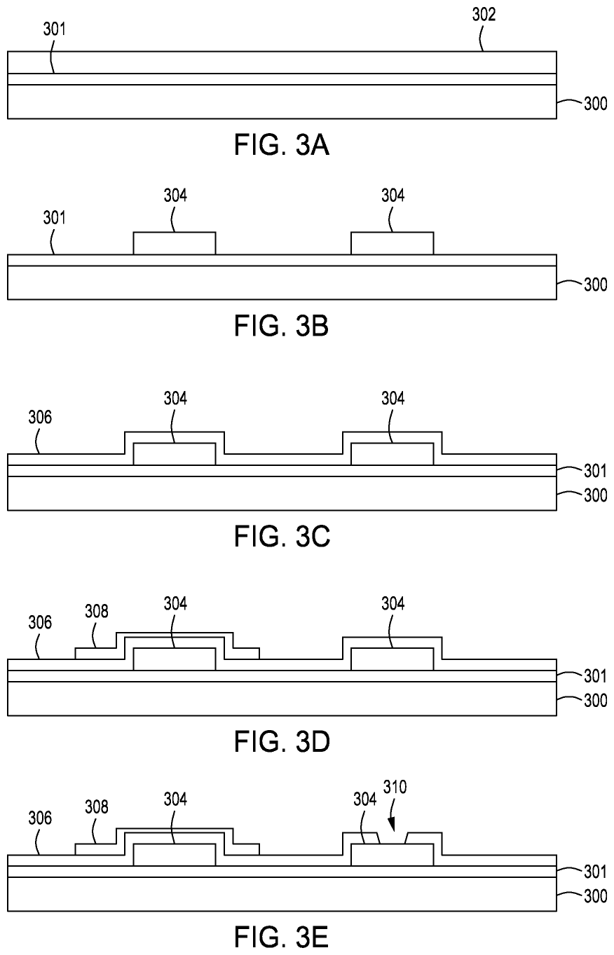

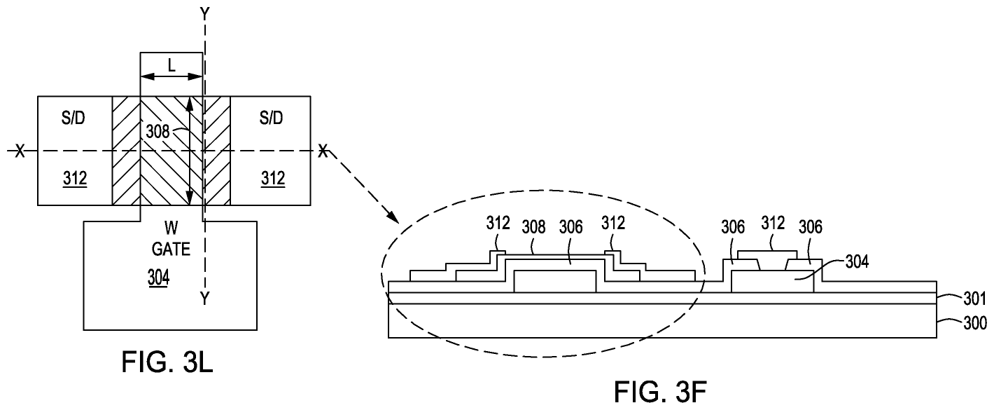

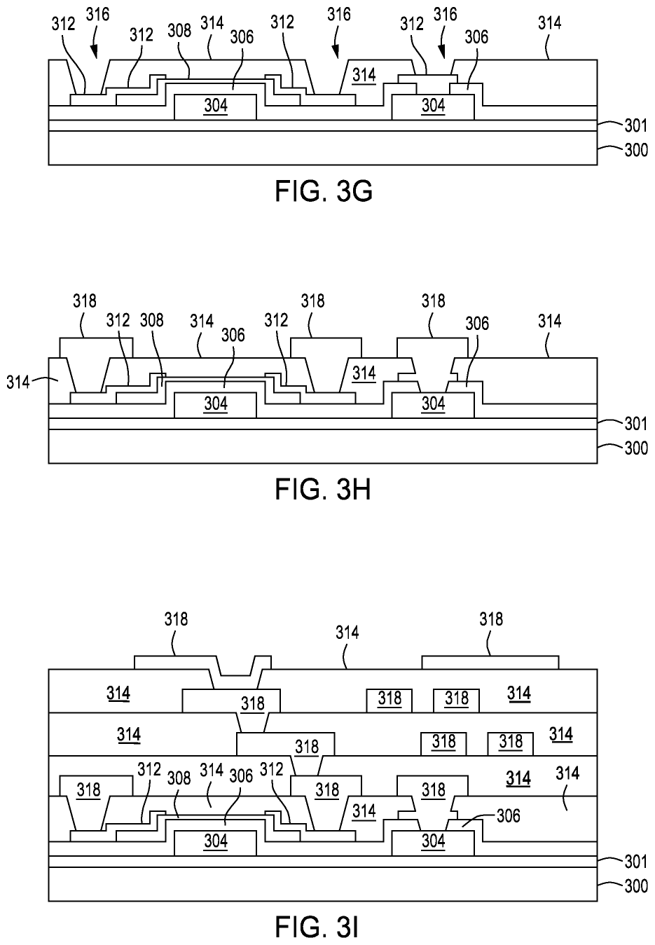

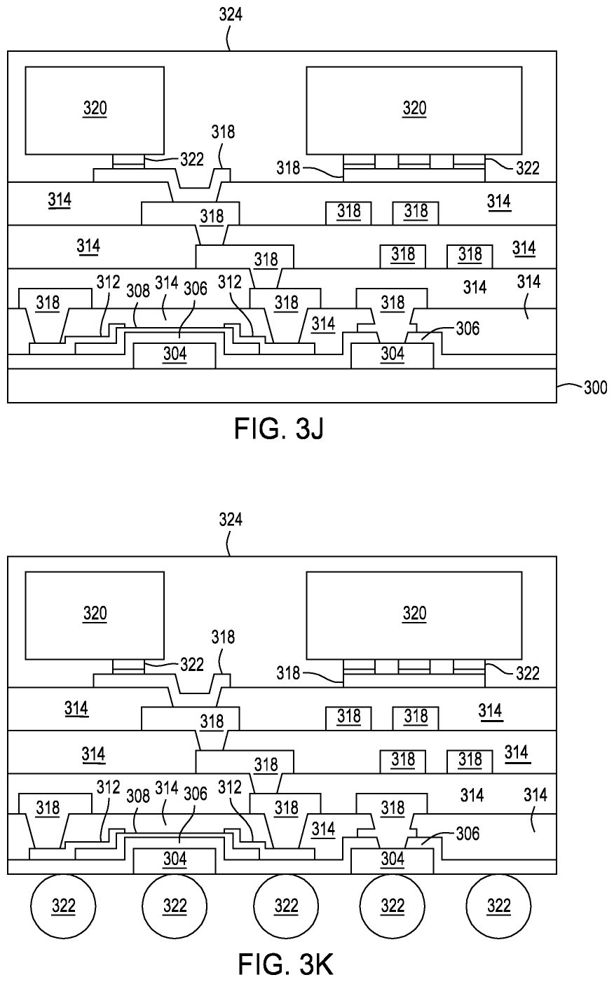

Continuing with reference to FIG. 1, the method 100 can be used to fabricate a thin film transistor (TFT) on one or more substrates. For example, in at least some embodiments, depending on an intended use of the TFT, a substrate can be a carrier substrate, which can be made from glass, a metal layer of one of a redistribution layer interposer (RDL) or a substrate interconnect, or at least one of a digital circuit, a dynamic random-access memory, or an integrated circuit (die), as will be described in greater detail below. In the embodiment of FIGS. 3A-3L, the TFT is described being fabricated on a substrate 300, such as a carrier substrate made from silicon, glass, or fiberglass, which can be embedded in one or more layers (e.g., polymer/metal layers) of an RDL interposer.

As noted above, the method 100 can be used for forming the TFT gate where gate metal is placed at a bottom layer, a top layer, or dual-gates (top and bottom layers). For illustrative purposes, the method 100 is described in terms of the TFT being embedded on a first layer (e.g., a bottom layer—bottom gated) of the RDL interposer. In embodiments where the TFT is embedded in a last layer (e.g., a top layer—top gated), the method 100 would use a reverse sequence of operations, and dual gated is combination of both top gated and bottom gated, which can provide better gate control.

Initially, the substrate 300 may be loaded into one or more of the Four FOUPS, such as 205A, 205B, 205C, and 205D. For example, in at least some embodiments, the substrate 300 can be loaded into FOUP 205A.

The method 100 includes, at 102, depositing a first metal layer 302 on the substrate 300 and etching the first metal layer to form one or more gate electrodes. For example, once loaded, the factory interface robot 238 can transfer the substrate 300 from the factory interface 204 to the processing platform 201 through, for example, the load lock chamber 206A. The vacuum robot 242 can transfer the substrate 300 from the load lock chamber 206A to and from one or more of the process chambers 214A-214D and/or the service chambers 216A and 216B. For example, the vacuum robot 242 can transfer the substrate 300 to the process chamber 214A to deposit the first metal layer 302 using one or more of the above-mentioned deposition processes. In at least some embodiments, the process chamber 214A can be configured to perform PVD (e.g., DC sputtering) to deposit the first metal layer, which can be at least one of titanium, copper, or molybdenum, or other suitable metal. In at least some embodiments, the first metal layer can be titanium. Additionally, in at least some embodiments, a release layer 301 can be coated on the substrate 300 prior to depositing the first metal layer 302 at 102. The release layer 301 can be made from any suitable release material. For example, in at least some embodiments, the release layer 301 can be made from organic material dissolvable with UV light, thermal treatment or mechanical peel.

At 102, PVD deposition can be performed at a pressure of less than about 10 mTorr, a DC power of about 10 kW to about 20 kW, and with one or more process gases, such as argon, at a flow rate of 20 sccm to about 60 sccm.

The first metal layer 302 can be deposited to one or more suitable thicknesses. For example, the thickness of the first metal layer 302 can be about 100 nm to about 1000 nm. In at least some embodiments, the first metal layer 302 can have a thickness of about 100 nm.

After the first metal layer 302 is deposited on the substrate 300 to a desired thickness, at 102, the vacuum robot 242 can transfer the substrate 300 from the process chamber 214A to the process chamber 214B. For example, the process chamber 214B can be configured to etch the first metal layer 302 using one or more suitable etch processes to form one or more gate electrodes, e.g., a gate electrode 304. For example, in at least some embodiments, the first metal layer 302 can be etched using a dry etch process and a masking layer (not shown) to form the gate electrode 304 (FIG. 3B). The masking layer can be deposited in the process chamber 214A prior to transferring the substrate 300 from the process chamber 214A to the process chamber 214B. The dry etch process can be performed at a pressure of about 10 mTorr to about 80 mTorr, RF source power of about 1000 W to about 3000 W, an RF bias power of about 500 W to about 1200 W, a cathode temperature of 0 to about −20° C., and one or more process gases (e.g., etch gases), such as C₄F₈, SF₆, Ar, etc.

Next, a 104, the method 100 includes depositing a dielectric layer 306 atop the gate electrode 304 (FIG. 3C). For example, the vacuum robot 242 can transfer the substrate 300 from the process chamber 214B to the process chamber 214C which can be configured to perform one or more of the above deposition processes. For example, the process chamber 214C can be configured to perform one or more CVD processes (e.g., PECVD) or PVD (e.g., pulse sputtering) to deposit the dielectric layer 306 atop the at least a gate electrodes 304. The dielectric layer 306 can be formed from a low-k or high-k dielectric material. In at least some embodiments, the dielectric layer 306 can be formed from a high-k dielectric material such as, for example, at least one of silicon oxide, silicon nitride, or aluminum nitride. In at least some embodiments, the dielectric layer 306 can be silicon oxide. The dielectric layer 306 can be deposited to one or more suitable thicknesses. For example, the thickness of the dielectric layer 306 can be about 10 nm to about 1000 nm. In at least some embodiments, the dielectric layer 306 can have a thickness of about 200 nm. The PECVD process can be performed at a pressure of about 1 Torr to about 10 Torr, an RF source power of about 1000 W to about 2000 W, RF bias power of about 100 W to about 1000 W, a temperature of about 100° C. to about 400° C., and with one or more process gases (e.g., for deposition), such as tetraethyl orthosilicate (TEOS), O₂, H₃.

Next, at 106, the method 100 can include depositing a semi-conductive oxide layer 308 atop the dielectric layer 106 to cover a portion of the gate electrode forming the transistor channel (FIG. 3D). For example, the vacuum robot 242 can transfer the substrate 300 from the process chamber 214C to the process chamber 214A to perform PVD to form a semi-conductive oxide layer 308 (e.g., to form a transistor channel). For illustrative purposes, the semi-conductive oxide layer 308 is shown deposited on the left gate electrode. The semi-conductive oxide layer 308 can be at least one of zinc oxide, aluminum doped zinc oxide (Al—ZO), indium-zinc oxide, indium-gallium-zinc-oxide (IGZO). For example, in at least some embodiments, the semi-conductive oxide layer 308 can be indium-gallium-zinc-oxide (IGZO). The semi-conductive oxide layer 308 can be deposited to one or more suitable thicknesses. For example, the thickness of the semi-conductive oxide layer 308 can be about 10 nm to about 2000 nm. In at least some embodiments, the semi-conductive oxide layer 308 can have a thickness of about 50 nm.

At 106, RF PVD deposition can be performed using similar process parameters as described above with respect to 102, e.g., at a pressure of less than about 10 mTorr, an RF power of about 10 kW to about 20 kW, and with one or more process gases, such as argon, at a flow rate of 20 sccm to about 60 sccm.

In at least some embodiments, at 106, one or more known etch processes and masking layers (not shown) can be used to facilitate covering the gate electrode 104. For example, in at least some embodiments, the semi-conductive oxide layer 308 can be deposited to cover (or substantially cover) the dielectric layer 106. Thereafter, a masking layer can be deposited and an etch process, such as a dry etch plasma or wet etch process, can be performed to remove the semi-conductive oxide layer 308 from the dielectric layer 306 (e.g., from the right gate electrode). The process chamber 214D can be configured to perform, for example, the dry etch process.

Next, at 108, the method includes etching the dielectric layer 306 from a portion of the gate electrode that is not covered by the semi-conductive oxide layer 308 to form a gate access via 310 (FIG. 3E). For illustrative purposes, as noted above, the semi-conductive oxide layer 308 is shown deposited on the left side of the gate electrode 304, so the dielectric layer 306 is etched from the right side of the gate electrode 304. The vacuum robot 242 can transfer the substrate 300 from the process chamber 214A to the process chamber 214B to etch the dielectric layer 306 from the right side of the gate electrode 304. Prior to transferring the substrate 300 from the process chamber 214A to the process chamber 214B, a masking layer can be deposited at the process chamber 214A. At 108, the process chamber 214B can be configured to perform a dry etch process to form the gate access via 310. At 108, the etch process can be performed at a pressure of about 10 mTorr to about 80 mT, an RF source power of about 1000 W to about 3000 W, an RF bias power of about 500 W to about 1200 W, a cathode temperature of about 0 to about −20° C., and one or more process gases, such as C₄F₈, SF₆, Ar, etc.

Next, at 110, the method 100 includes depositing a second metal layer 312 atop the dielectric layer 306 and the semi-conductive oxide layer 308, and within the gate access via 310, e.g., for gate, source, drain metal connectivity formation, (FIG. 3F). The vacuum robot 242 can transfer the substrate 300 from the process chamber 2146 to the process chamber 214A. The second metal layer 312 can be at least one of titanium, copper, or molybdenum. In at least some embodiments, the second metal layer is copper. The second metal layer 312 can be deposited to one or more suitable thicknesses. For example, the thickness of the second metal layer 312 can be about 1 μm to about 5 μm. In at least some embodiments, the second metal layer can have a thickness of about 1000 nm. Additionally, a length L of the semi-conductive oxide layer 308 measured along an X axis (FIG. 3L), e.g., between the source/drain (S/D)) formed at 110, can be about 1 μm to about 20 μm. Similarly, a width W of the semi-conductive oxide layer 308 measured along a Y axis (FIG. 3L), e.g., between the source/drain (S/D)) formed at 110, can be about 1 μm to about 20 μm.

At 110, PVD deposition can be performed at a pressure of less than about 10 mTorr, a DC power of about 10 kW to about 20 kW, and with one or more process gases, such as argon, at a flow rate of 20 sccm to about 60 sccm.

In at least some embodiments, at 110, one or more of the above-described etch processes and masking layers (not shown) can also be used for gate, source, drain metal connectivity formation.

Next, the method 100 can include depositing a polymer coating layer 314 (e.g., a photosensitive polymer coating layer, FIG. 3G) to cover the second metal layer 312 and mask patterned and developed of the polymer coating layer 314 to form vias 316 exposing the second metal layer 312 (e.g., to develop polymer layers of the RDL interposer). The polymer coating layer 314 can be made from one or more known polymers that are suitable for developing the layers of the RDL interposer. For example, in at least some embodiments, the polymer coating layer 314 can be made from polyamide, phenolic, polybenzoxazoles, epoxy. The polymer coating layer 314 can be deposited to a thickness of about 1 μm to about 10 μm using spin coater, e.g., a spin coater with developing and baking capability.

For example, after the vias 316 are formed in the polymer coating layer 314, the vacuum robot 242 can transfer the substrate 300 for depositing a third metal (e.g., titanium, copper, or molybdenum) as barrier seed metal. The photoresist will be coated and lithography patterned to form the design of redistribution layer. The wafer then plated with copper to fill the vias 316 and form an at least one metal contact atop the polymer coating layer 314. For example, as shown in FIG. 3H, three metal contacts 318 are formed in the vias 316. The third metal can be plated to a thickness of about 1 μm to about 5 μm.

The processes of the method 100 shown in FIGS. 3G and 3H can be repeated to develop as many layers of polymer and metal contacts as necessary, as shown in FIG. 3I. Thereafter, the method 100 can optionally include connecting one or more electrical devices 320 (e.g., using known connection processes/apparatus) to the metal contacts 318 formed on a last polymer coating layer (FIG. 3J). For example, in at least some embodiments, the one or more electrical devices 320 can comprise, but is not limited to, at least one of a digital circuit, a dynamic random-access memory, or an integrated circuit (die). In at least some embodiments, under bump metallization can be used to form solder bumps 322 for connecting to metal contacts on the one or more electrical devices 320 and to the metal contacts 318. The inventors have found that connecting the one or more electrical devices 320 to the RDL interposer including the TFT embedded therein, provides signal buffering having a shorter path (e.g., no silicon substrate/TSV are needed), enables better performance, provides a relatively low system integration cost alternative, provides interconnect redundancy for yield management, provides multiplexing/demultiplexing between to integrated circuits with a reduction of metal layers when compared to conventional RDL interposers, which can sometimes require 1:1 matching of I/O channels and greater than six layers of high density interconnects.

In at least some embodiments, the method 100 can optionally include removing the substrate 300 (and the release layer 301 if provided) after connecting the one or more electrical devices 320 to the metal contacts 318 and performing under bump metallization to form solder bumps 322 on a bottom surface of the dielectric layer (e.g., the formed TFT embedded in the first polymer coating layer). In some embodiments, one or more suitable molds 324 can be deposited to cover the one or more electrical devices 320, the metal contacts 318, and the last polymer coating layer (FIG. 3K).

The methods described herein can also be used in other FanOut process schemes. For example, while the method 100 has been described herein as an RDL first FanOut process scheme (e.g., RDL 1st is creating the RDLs of interconnects before connecting to the die/chips), the method 100 is not so limited. For example, the FanOut process scheme can include an RDL last (e.g., the dies are embedded/reconstituted into a wafer format and then the RDLs are formed on top of reconstituted package to form external connectivity).

While the foregoing is directed to embodiments of the present disclosure, other and further embodiments of the disclosure may be devised without departing from the basic scope thereof.

1. A method of processing a substrate, comprising:
depositing a first metal layer on a substrate and etching the first metal layer to form a gate electrode;
depositing a dielectric layer atop the gate electrode;
depositing a semi-conductive oxide layer atop the dielectric layer to cover a portion of the gate electrode;
etching the dielectric layer from a portion of the gate electrode that is not covered by the semi-conductive oxide layer to form a gate access via; and
depositing a second metal layer atop the dielectric layer and the semi-conductive oxide layer, and within the gate access via.

2. The method of claim 1, wherein depositing the first metal layer comprises depositing at least one of titanium, copper, or molybdenum.

3. The method of claim 1, wherein the first metal layer has a thickness of about 100 nm.

4. The method of claim 1, wherein depositing the dielectric layer comprises depositing at least one of silicon oxide, silicon nitride, or aluminum nitride.

5. The method of claim 1, wherein the dielectric layer has a thickness of about 200 nm.

6. The method of claim 1, wherein depositing the semi-conductive oxide layer comprises depositing at least one of zinc oxide, aluminum doped zinc oxide (Al—ZO), indium-zinc oxide, indium-gallium-zinc-oxide (IGZO).

7. The method of claim 1, wherein the semi-conductive oxide layer has a thickness of about 50 nm.

8. The method of claim 1, wherein etching the dielectric layer comprises performing a dry etch process.

9. The method of claim 1, wherein depositing the second metal layer comprises depositing at least one of titanium, copper, or molybdenum.

10. The method of claim 1, wherein the second metal layer has a thickness of about 100 nm.

11. The method of claim 1, further comprising depositing a polymer coating layer to cover the second metal layer and etching the polymer coating layer to form vias exposing the second metal layer.

12. The method of claim 11, further comprising depositing a third metal to fill the vias and form an at least one metal contact atop the polymer coating layer.

13. The method of claim 12, further comprising connecting at least one of a digital circuit, a dynamic random-access memory, or an integrated circuit to the at least one metal contact.

14. The method of claim 13, further comprising removing the substrate after connecting the at least one of the digital circuit, the dynamic random-access memory, or the integrated circuit to the at least one metal contact and performing under bump metallization to form solder bumps on a bottom surface of the dielectric layer.

15. The method of claim 1, wherein the substrate is one of a carrier substrate made from silicon, glass or fiberglass, a metal layer of one of a redistribution layer interposer or a substrate interconnect, or at least one of a digital circuit, a dynamic random-access memory, or an integrated circuit.

16. A non-transitory computer readable storage medium having stored thereon instructions that when executed by a processor performs a method of processing a substrate, comprising:
depositing a first metal layer on a carrier substrate and etching some of the first metal layer to form a gate electrode;
depositing a dielectric layer atop the gate electrode;
depositing a semi-conductive oxide layer atop the dielectric layer to cover a portion of the gate electrode;
etching the dielectric layer from a portion of the gate electrode that is not covered by the semi-conductive oxide layer to form a gate access via; and
depositing a second metal layer atop the dielectric layer and the semi-conductive oxide layer, and within the gate access via.

17. The non-transitory computer readable storage medium of claim 16, wherein depositing the first metal layer comprises depositing at least one of titanium, copper, or molybdenum, and wherein the first metal layer has a thickness of about 100 nm.

18. The non-transitory computer readable storage medium of claim 16, wherein etching some of the first metal layer comprises performing a dry etch process.

19. The non-transitory computer readable storage medium of claim 16, wherein depositing the dielectric layer comprises depositing at least one of silicon oxide, silicon nitride, or aluminum nitride, and wherein the dielectric layer has a thickness of about 200 nm.

20. An apparatus for use with a thin film transistor, comprising:
a first metal layer deposited on a carrier substrate and having a gate electrode formed thereon;
a dielectric layer deposited atop the gate electrode;
a semi-conductive oxide layer deposited atop the dielectric layer to cover a portion of the gate electrode;
a gate access formed in a portion of the gate electrode that is not covered by the semi-conductive oxide layer; and
a second metal layer is deposited atop the dielectric layer and the semi-conductive oxide layer, and within the gate access via.
